(19) United States
(12) Patent Application Publication
(10) Pub. No.: US 2024/0035570 A1
(43) Pub. Date: Feb. 1, 2024

(54) PISTON RINGS AND METHODS OF MANUFACTURE

(71) Applicant: NANOFILM VACUUM COATING (SHANGHAI) CO., LTD., Shanghai (CN)

(72) Inventors: Chao DU, Singapore (SG); Xu SHI, Singapore (SG); Ming Chu YANG, Singapore (SG); Bo ZHANG, Singapore (SG)

(21) Appl. No.: 18/250,558

(22) PCT Filed: Nov. 12, 2021
(86) PCT No.: PCT/EP2021/081537

§ 371 Date: Apr. 26, 2023

(30) Foreign Application Priority Data
Nov. 13, 2020 (WO) PCT/CN2020/128765
Dec. 18, 2020 (EP) 20215731.9
Apr. 2, 2021 (CN) 202110360718.1

(51) Int. Cl. F16J 9/26; C23C 14/06; C23C 14/24

(52) U.S. Cl. CPC F16J 9/26; C23C 14/0605; C23C 14/24

(57) ABSTRACT

A method of coating a piston ring comprises: providing at least first and second piston rings in a coating chamber; spacing the piston rings apart, so that the first piston ring is spaced from and not in contact with the second piston ring, and applying a ta-C coating to the piston rings, whereby the spacing between the adjacent piston rings enables simultaneous coating of upper, outer and lower piston ring surfaces of the first and second piston rings during rotation of rings in a plane co-planar with the coating beam. Piston rings are obtained comprising a substantially hydrogen free ta-C coating of 0.1 to 8 microns on at least their lower surface.

### INTRODUCTION

The present invention relates to piston rings, coatings for piston rings, methods of manufacturing piston rings, methods of coating piston rings and apparatus for coating piston rings.

### BACKGROUND TO THE INVENTION

Piston rings are required in all piston engines, including, among others, many engines for automobiles, marine vehicles and aeroplanes. There are different types of commonly used piston engines, including spark-ignition engines and diesel engines.

Piston rings are available and used in many different shapes and sizes. Common piston ring configurations include rectangular, barrel, keystone, torsional twist, taper face and dykes. As a generality all are substantially rectangular in cross-section though differing in some surface profile respects.

Piston rings are often made from cast iron (e.g. grey cast iron), aluminium, steel (e.g. stainless steel) or alloys of copper (e.g. bronze). To improve the properties of the piston rings, they may be formed from an alloy. Common materials for alloying are chromium, nickel, molybdenum, copper and vanadium among others. Known piston rings are described e.g. in EP 1479946, JP 2006/283970 and WO 2017/186915, and EP 3026302 describes a jig for holding piston rings during manufacture.

A known problem with piston rings is reduced movement of the piston ring in the piston ring groove due to sticking or welding of the piston ring to the piston ring groove as a consequence of the harsh conditions and high temperature in the cylinder. Reduced movement of the piston ring in the groove is a problem since this may reduce contact and therefore sealing of the piston ring to the cylinder, increasing oil and/or fuel consumption and reducing the efficiency of the cylinder.

Pistons typically have more than one ring, with different rings serving different purposes. Welding of the piston ring to the groove is a particular problem for the top ring (closest to the cylinder head, also referred to as a compression ring) since this ring experiences the harshest conditions. The welding of the top piston ring to the groove tends to happen between the lower surface of the piston ring and the lower surface of the piston ring groove.

It is known to coat the top and bottom surfaces of a stainless steel piston ring with nitride or chromium with the intention to reduce the welding issue. However, nitride coatings exhibit poor corrosion resistance and low bending strength. Chromium has a maximum plating thickness of 5 μm since grain size increases with plating thickness leading to a rough surface that cannot be eliminated by polishing. This is a problem since the industry standard coating thickness is 15 μm in order to meet durability criteria.

There is therefore a need for improved piston rings overcoming the problem of welding to the groove and without the disadvantages of chromium and nitride coatings known in the art.

Amorphous carbon is a free, reactive form of carbon which does not have a crystalline form. Various forms of amorphous carbon films exist and these are usually categorised by the hydrogen content of the film and the sp²:sp³ ratio of the carbon atoms in the film.

In an example of the literature in this field, amorphous carbon films are categorised into 7 categories (see table below taken from “Name Index of Carbon Coatings” from Fraunhofer Institut Schich- and Oberflächentechnik):

Amorphous Carbon Films

| Hydrogen-Free | | | Hydrogenated | | | |
|---|---|---|---|---|---|---|
| | | Modified | | | Modified with | |
| Unmodified | | With metals | Unmodified | | Metals | Non-metals |
| sp² | sp³ | sp² | sp2 or sp³ | sp³ | sp² | sp² |
| Hydrogen- | Tetrahedral, | Metal- | Hydrogenated | Tetrahedral, | Metal-containing, | Non-metal |
| free | hydrogen- | containing, | amorphous | hydrogenated | hydrogenated | containing |
| amorphous | free | hydrogen- | carbon | amorphous | amorphous carbon | hydrogenated |
| carbon | amorphous | free | | carbon | | amorphous |
| | carbon | amorphous | | | | carbon |
| | | carbon | | | | |
| a-C | ta-C | a-C:Me | a-C:H | ta-C:H | a-C:H: Me | a-C:H:X |

Amorphous and tetrahedral amorphous carbon (a-C and ta-C) are characterised in that they contain little or no hydrogen (less than 10% mol, generally less than 5% mol, typically less than 2% mol).

Tetrahedral hydrogen-free amorphous carbon (ta-C) is further characterised in that it contains a high content of sp³ hybridised carbon atoms (typically greater than 80% of the carbon atoms being in the sp³ state).

An object of the invention is thus to provide alternative piston rings, coatings for piston rings, methods of manufacturing piston rings, methods of coating piston rings and apparatus for coating piston rings to address one or more of the problems discussed above. An object of preferred embodiments is to provide improved piston rings and associated methods and apparatus to ameliorate or overcome one or more identified problems.

### SUMMARY OF THE INVENTION

Accordingly, the invention provides a piston ring comprising a ta-C coating on its lower/bottom surface.

Also provided is a method of coating a piston ring, comprising providing a piston ring and applying to the lower surface of the piston ring a coating of ta-C, e.g. by providing at least first and second piston rings in a coating chamber; spacing the piston rings apart, so that the first piston ring is spaced from and not in contact with the second piston ring, whereby the spacing between the adjacent piston rings enables simultaneous coating of upper, outer and lower piston ring surfaces of the first and second piston rings.

A jig is further provided, for holding a plurality of piston rings during coating, comprising:
a first station for holding a first piston ring,
a second station for holding a second piston ring,
wherein the first and second piston rings are held spaced apart and substantially co-axially with each other.

Piston rings of the invention are advantageously coated on at least their lower surface with a ta-C coating, providing welding/failure resistance during use in an internal combustion engine. Preferred piston rings of the invention are compression rings.

Details of the Invention

A piston ring of the invention comprises a ta-C coating on its lower/bottom surface.

As discussed above, the term “tetrahedral amorphous carbon” (ta-C or TAC) as used herein refers to amorphous carbon having a low hydrogen content and a low sp² carbon content.

Ta—C is a dense amorphous material described as composed of disordered spa, interlinked by strong bonds, similar to those that exist in disordered diamond (see Neuville S, “New application perspective for tetrahedral amorphous carbon coatings”, QScience Connect 2014:8, http://dx.doi.org/10.5339/connect.2014.8). Due to its structural similarity with diamond, ta-C also is a very hard material with hardness values often greater than 30 GPa.

For example, the ta-C may have a hydrogen content less than 10%, typically 5% or less, preferably 2% or less (for example 1% or less). The percentage content of hydrogen provided here refers to the molar percentage (rather than the percentage of hydrogen by mass). The ta-C may have an sp² carbon content less than 30%, typically 20% or less, preferably 15% or less. Preferably, the ta-C has a hydrogen content of 2% or less and an sp² carbon content of 15% or less. The ta-C is preferably not doped with other materials (either metals or non-metals). In preferred embodiments of the invention, as described in examples set out in detail below, the piston rings are coated with substantially hydrogen-free ta-C.

Piston rings are generally circular, or can be ovoid or elliptical, in plan, when viewed from above, depending upon the shape of the piston/cylinder they are designed for and fit around. In cross section each side of the ring is generally rectangular, having an inner surface facing the outer surface of the piston, an outer surface adjacent the combustion chamber wall and respective upper and lower surfaces. The upper surface is that towards the cylinder head and which receives the impact of pressure in the cylinder head following ignition, while the lower surface is away from the cylinder head.

Typically, in use the lower surface lies against an upper-facing surface of a groove or channel in the piston holding the ring in place.

Suitably, the ta-C coating extends over at least 50% of the surface. Referring to the lower surface by way of example, the coating may extend from the junction with the outer surface towards and at least halfway to the inner edge of the ring. Preferably at least 75% and more preferably substantially all of the lower surface is coated, though the coating depth may vary as a result of the coating process, which in embodiments described below deposits a greater depth of ta-C towards the outer edge of the ring.

Hence in embodiments of the invention, a piston ring is defined by being substantially rectangular in cross section, having upper, outer, lower and inner surfaces, and being coated on its lower surface with ta-C.

Piston rings of the invention may be coated on their lower surface, suitably also on their upper surface, and may also be coated in addition on their outer surface (that which slides against the combustion chamber wall during reciprocation of the piston).

In operation of an engine, high temperatures are experienced in the chamber and by the piston and piston ring. Pressure from the ignitions forces the lower surface of the ring onto its seat/location, on the upper-facing surface of the groove or channel in the piston. There may be relatively little movement of the ring with respective to its seat. The coating reduces the risk of sticking of the ring onto the piston during use, e.g. sticking due to welding of touching surfaces, which sticking prevents movement of the ring (e.g. laterally) relative to the piston and can increase wear and/or oil and/or fuel consumption and may lead to or contribute to engine failure. A ta-C coating on the ring outer surface, when present, is for improvement especially of wear resistance.

The ta-C coating may have a thickness of up to 10 μm on lower and, where present, upper surfaces. Suitable thicknesses are also from 0.1 to 8 μm, especially 0.2 μm or greater and especially 5 μm or less. Specific embodiments of the invention have coating thicknesses in the range 1-2 μm on lower and upper surfaces. As mentioned, this may vary slightly along the length of the lower surface, though preferably the thickness is maintained at least from the outer edge of the ring until 50% of the way along the surface towards the centre.

The ta-C coating may have a thickness of up to 20 μm on the outer surface. Suitable thicknesses are also from 1 to 10 μm, especially 2 μm or greater and especially 8 μm or less. Specific embodiments of the invention have coating thicknesses in the range 5-6 μm on the outer surface. The coating thickness may vary slightly however the thickness is usually substantially consistent along the outside surface.

In general, the thickness of the coating on the lower surface or, when present, the lower and upper surfaces, increases in depth towards the outer edge of the piston ring compared with its depth at the centre of the lower surface, or the lower and upper surfaces, of the piston ring. The thickness of the coating, when present, on the outer surface tends to be fairly consistent as that surface generally faces the coating sources/coating beam during the coating process.

To function as wear and stick-resistant it is preferred the ta-C has a minimal hardness. Generally, the coating has a hardness of 500 HV or greater, suitably 1000 HV or greater. The hardness is generally up to 4000 HV, suitably up to 3000 HV.

Further the coating may comprise one or two or a multiplicity of ta-C layers. In examples of the invention, the coating comprises a first ta-C coating layer and a second ta-C coating layer, wherein the first layer has a hardness of 1000-4000 HV and the second layer has a hardness that is in the range 500-2500 HV and is at least 500 HV less hard than the hardness of the first coating. In a specific embodiment of the invention, the first layer was about 1800-3000 HV and the second was about 800-1700 HV.

The invention is believed to apply in general to piston rings of any material. However, especially suitable materials for the piston rings include cast iron (e.g. grey cast iron). Piston rings of the invention may also be made of aluminium, steel (e.g. stainless steel), alloys of copper (e.g. bronze), and other alloys e.g. alloys of steel, iron, aluminium with one or more of chromium, nickel, molybdenum, copper and vanadium.

Also provided by the invention are methods of manufacture of piston rings. A method of the invention for coating a piston ring comprises providing a piston ring, and applying to the lower surface of the piston ring a coating of ta-C.

Preferred methods may comprise applying the coating simultaneously to the upper, lower and outer surfaces of the piston ring. This may also be convenient due to the nature of arranging rings to be coated in the coating machine. In this context, “simultaneous” refers to coating upper, lower and outer surfaces as part of the same coating process. It also suitably refers to using a coating beam with a horizontal thickness in excess of the thickness (also referred to as height) of the piston rings being coated so that at least lower and outer surfaces are coated at exactly the same time and preferably all of the upper, lower and outer surfaces of the piston ring can be coated at exactly the same time.

The ta-C coating may be deposited using known technology, e.g. physical vapor deposition, of which one known technique is cathodic vapor arc deposition methods. In this method, an electric arc is used to vaporize material from a cathode target. Consequently, the resulting vaporized material condenses on a substrate to form a thin film of coating. Cathode arc deposition of tetrahedral amorphous carbon, metallic, dielectric and other such coatings is known in the art and offers the potential for deposition of thin films of high quality.

The coating of the present invention is typically deposited by FCVA and/or by sputtering, and machines and processes for both sputter and ta-C deposition are conventional and known in the art and not features of the present invention. An example of a suitable deposition method is described in WO 2009/151404. A further example of a suitable deposition method is described in WO 2020/187744—in particular the use of an adhesion promoting layer is described in this application. The coating of the present invention is preferably deposited by FCVA. As appreciated by the skilled person, FCVA apparatus produce a coating beam comprising positively charged, C⁺ ions for depositing ta-C coatings.

Preferred methods of coating a piston ring according to the invention comprise rotating the piston ring in a single plane during coating; as noted this can be achieved by mounting and rotating the ring on a turntable which itself rotates, though in the same plane. Preferred methods of coating a piston ring according to the invention comprise directing a coating beam substantially orthogonally to the outer surface of the piston ring. In particular, and as described below with reference to examples, preferred methods comprise rotating the piston ring in a single plane during coating and directing a coating beam substantially orthogonally to the piston ring, wherein the beam is in the same plane as or parallel with the plane of rotation of the piston ring. Hence the ring rotation may be parallel with or coplanar with the coating beam.

It is an advantage to coat the lower surface of many piston rings at the same time, as chamber preparation time is long and, as ever, there is a desire to reduce average coating times and costs. Hitherto, while coating outer surface of rings was possible, coating also the lower (and optionally upper) surfaces was not. According to the invention, a novel orientation/disposition of rings in the chamber now makes this possible.

In embodiments of the invention, methods comprise (i) providing at least first and second piston rings in a coating chamber, and (ii) spacing the piston rings apart, so that the first piston ring is spaced from and not in contact with the second piston ring. It is found that applying a coating from the side, towards the outer surface(s) of the ring(s), not only coats the outer surface(s) but surprisingly also allows deposition of ta-C coating on and along the lower/upper surface(s) that are parallel with or at most angled at a very small angle obliquely to the coating source (typically a beam of ions). Coating is achieved despite the lower surfaces of the rings being close to parallel with the coating beam or at a small angle thereto. Depth of coating on the lower/upper surfaces is typically not as deep/thick as on the outer surface of the rings (facing the beam) but is deep enough to result in a protective, functional ta-C coating to reduce wear and sticking, providing improved, coated rings.

It is accordingly found that the spacing between the adjacent piston rings enables simultaneous coating of upper, outer and lower piston ring surfaces of the first and second piston rings. Mounting the piston rings substantially co-axially is convenient. This enables a stack of rings to be prepared in which rings can be evenly spaced, for efficient use of the available volume inside the chamber. The spacing between the first and second piston rings is sufficient to allow coating to be deposited along upper and lower ring surfaces. Suitably the spacing is at least 50% the height of the first piston ring, or at least 100% the height of the first piston ring.

Typically, methods comprise rotating the piston ring(s) while applying the coating. Also typically, many rings are coated at the same time in stacks mounted on a turntable. In specific methods, described in more detail below, coating comprises mounting a first stack of piston rings at a first location on a turntable, mounting a second stack of piston rings at a second location on the turntable, and rotating the first and second stacks and rotating the turntable while applying the coating. For even and efficient coating, methods comprise rotating (i) the stacks, and (ii) the turntable in opposite directions, one clockwise and the other anti-clockwise. Rotation speed of the stacks and the turntable may differ. Preferably, the methods comprise rotating the rings in a single plane during coating; the plane is preferably substantially parallel with the plane of the coating beam.

Still further provided by the invention is a jig for holding a plurality of piston rings during coating, comprising:
a first station for holding a first piston ring,
a second station for holding a second piston ring,
wherein the first and second piston rings are held spaced apart and substantially co-axially with each other.

Preferably, the jig comprises:
a central column,
a plurality of protruding arms, disposed along at least a portion of the length of the central column and extending outwards from the central column,
on each protruding arm, a support surface to support a piston ring,
whereby a stack of at least 10 piston rings can be held substantially co-axially each spaced apart by substantially the same distance from the adjacent ring or rings.

Suitably, the jig is adjustable and the distance between adjacent rings may be in the range 1 mm-10 mm.

Ta—C is a dense amorphous material described as composed of disordered spa, interlinked by strong bonds, similar to those that exist in disordered diamond (see Neuville S, “New application perspective for tetrahedral amorphous carbon coatings”, QScience Connect 2014:8, http://dx.doi.org/10.5339/connect.2014.8). Due to its structural similarity with diamond, ta-C also is a very hard material with hardness values often greater than 30 GPa.

Hardness is suitably measured using the Vickers hardness test (developed in 1921 by Robert L. Smith and George E. Sandland at Vickers Ltd; see also ASTM E384-17 for standard test), which can be used for all metals and has one of the widest scales among hardness tests. The unit of hardness given by the test is known as the Vickers Pyramid Number (HV) and can be converted into units of pascals (GPa). The hardness number is determined by the surface area of the indentation which is tested by a certain load. As examples, Martensite a hard form of steel has HV of around 1000 and diamond can have a HV of around 10,000 HV (around 98 GPa). Hardness of diamond can vary according to precise crystal structure and orientation but hardness of from about 90 to in excess of 100 GPa is common.

### EXAMPLES

The present invention is now described in more and specific details with reference to the accompanying drawings in which:

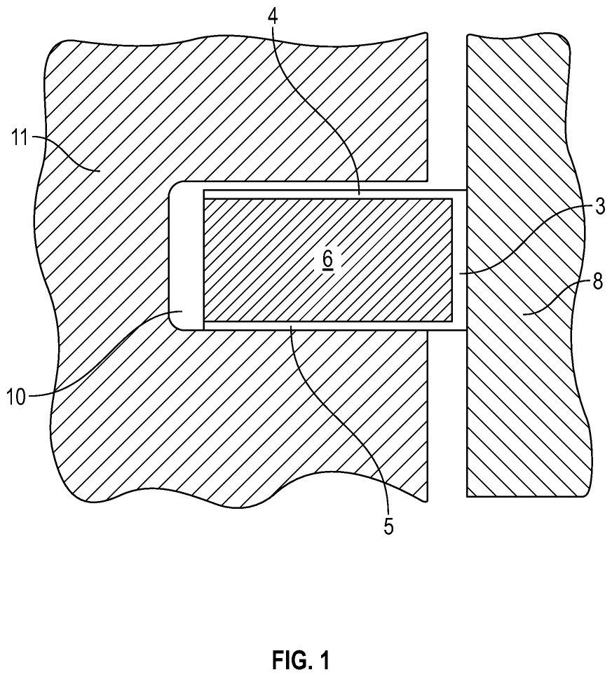

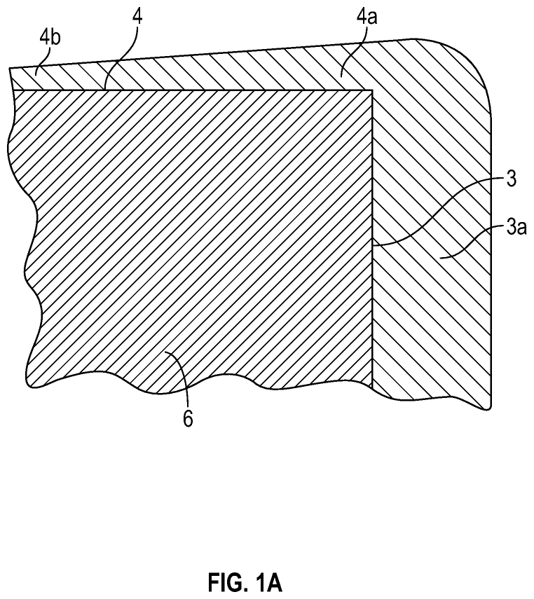

FIG. 1 shows a schematic cross-section of a piston ring of the invention in a piston ring groove;

FIG. 1A shows a schematic cross-section of the detail of the top right hand corner of the piston ring of FIG. 1;

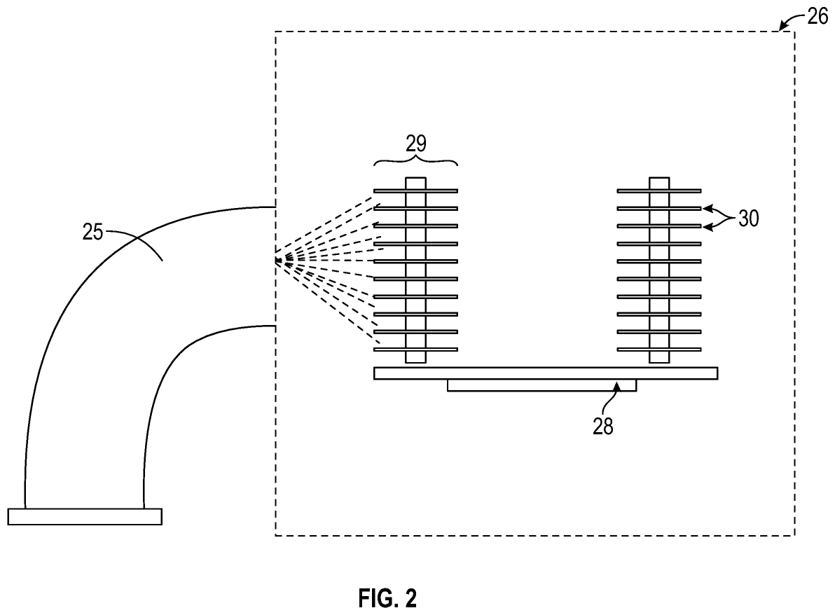

FIG. 2 shows a schematic side view of piston rings mounted on a jig of the invention during a coating process, wherein the outside, top and bottom surfaces of the piston ring are all coated in one step; and

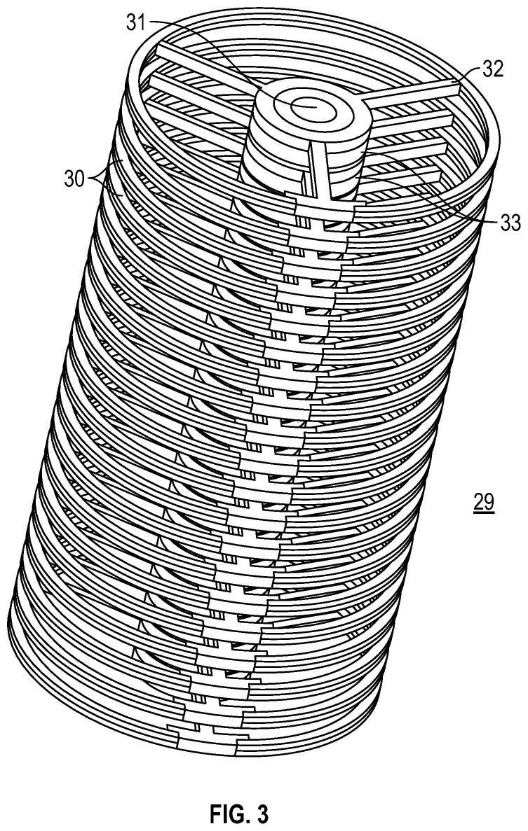

FIG. 3 shows a more detailed schematic view of the jig of FIG. 2 loaded with multiple piston rings.

FIG. 1 shows a highly schematic side view in cross section of cast-iron piston ring 6 coated with ta-C on the outside/outer surface 3, top/upper surface 4 and bottom/lower surface 5. Coating depth is approximately 0.5-2 microns on surfaces 4 and 5, varying from about 0.5 microns at the inner edge, towards the piston 11 (left hand side of the drawing) and up to about 2 microns at the (right hand) outer edge of the piston ring, towards the inside surface of the wall of chamber 8. Coating depth on the outer surface 3 is approximately 4-6 microns and of greater depth than on surfaces 4 and 5. The outside surface 3 is in contact with and in use reciprocates on the wall of the chamber 8 and the bottom surface 5 of the piston ring is in contact with the bottom surface of the piston ring groove 10 of the piston 11. In testing of the invention, provision of the ta-C coating on surface 5 of a compression ring reduces welding/sticking problems compared with rings that are uncoated on this surface.

More detail is provided schematically in FIG. 1A, of how the coating depth on upper surface 4 is greater towards the outside, i.e. greater in region 4a towards the outer edge of the ring and less in region 4b towards the inside of the ring. Coating depth, as a result of the coating process, is greatest in region 3a on outer surface 3.

FIGS. 2 and 3 show schematically a jig of the invention being used in a coating process in a coating machine. The machine has a plasma source 25 from which a plasma beam of carbon ions is emitted into a chamber 26. Inside the chamber 26 there are multiple jigs 29 on a turnplate 28. Each jig 29 comprises a central support rod 31 onto which fits multiple support frames 32 each of which holds a piston ring 30, forming a stack of spaced rings. When in use, the plasma source is fixed in position and the turnplate rotates in the opposite direction to the handle ring fixtures enabling the plasma to coat upper, lower and outer surfaces of all piston rings in the chamber. Rotation of the rings on the jig is substantially in a single plane. Again, the representation is highly schematic as the coating beam of charged particles is directed generally orthogonally to the outer surfaces of the rings on the jig, hence depositing a deeper coating on outer surfaces 3 of the many piston rings stacked on top of each other in the jig and at the same time, and surprisingly, still depositing a coating layer on both upper and lower surfaces of the rings.

FIG. 3 shows a more detailed view of a jig 29 loaded with piston rings. The central support rod 31 holds the support frames 32 which in turn hold the piston rings 30. The support frames 32 are spaced apart on the support rod 31 by support tubes 33. The length of the support tubes 33 determine the spacing between the piston rings 30 on the support rod 31. During coating with ta-C, the coating beam is substantially orthogonal to the piston ring outer surface 3 but a coating is found to be applied nevertheless to upper, lower and outer surfaces of all piston rings in the chamber. It is found that altering the size of support tubes 33 alters the spacing between adjacent rings and alters the thickness of the coating on the top and bottom surface of each piston ring.

To make piston rings of the invention jigs were loaded with uncoated, cast-iron rings, and placed into the coating chamber which was evacuated. An adhesion promoting layer was applied and then the FCVA source was operated with the turntable and stacks rotating in opposite directions until an average ta-C coating depth of 1-2 microns was deposited onto lower and upper piston ring surfaces (based on previous calibration coating runs).

The invention thus provides piston rings coated with ta-C, and methods and apparatus therefor.

1-26. (canceled)

27. A method of coating a piston ring, comprising:
providing a piston ring having upper, lower and outer surfaces;
applying a coating of ta-C simultaneously to the upper, lower and outer surfaces of the piston ring.

28. The method of claim 27, wherein the coating is applied using a filtered cathode vacuum arc process.

29. The method of claim 27 for coating at least first and second piston rings each having upper, lower and outer surfaces, comprising
providing the at least first and second piston rings in a coating chamber;
spacing the at least first and second piston rings apart, so that the first piston ring is spaced from and not in contact with the second piston ring,
whereby the spacing between the adjacent piston rings enables simultaneous coating of the upper, outer and lower piston ring surfaces of the first and second piston rings.

30. The method of claim 27, comprising applying the coating using a coating beam with a horizontal thickness in excess of the horizontal thickness of the piston ring.

31. The method of claim 29, wherein the spacing between the first and second piston rings is at least 50% of the horizontal thickness of the first piston ring.

32. The method of claim 27, comprising rotating the piston ring in a single plane during coating.

33. The method of claim 27, comprising directing a coating beam substantially orthogonally to the outer surface of the piston ring.

34. The method of claim 27, wherein the hardness of the ta-C coating is 1000 HV or greater.

35. A method of coating a piston ring, comprising:
providing a piston ring having upper, lower and outer surfaces;
rotating the piston ring in a plane; and
directing a coating beam of carbon ions generated using a filtered cathode vacuum arc process substantially orthogonally to the outer surface of the piston ring, wherein the beam is in the same plane as the plane of rotation of the piston ring and wherein the beam has a horizontal thickness in excess of the horizontal thickness of the piston ring,
thereby applying a coating of ta-C simultaneously to the upper, lower and outer surfaces of the piston ring.

36. The method of claim 35, wherein the thickness of the coating on the outer surface of the piston ring is up to 20 μm.

37. The method of claim 35, wherein the thickness of the coating on the upper and lower surfaces of the piston ring is up to 10 μm.

38. The method of claim 35, wherein the hardness of the ta-C coating is 1000 HV or greater.

39. A piston ring, having upper, lower and outer surfaces and an outer edge at a junction between the lower surface and the outer surface, wherein the piston ring is coated with a coating of ta-C on the upper, lower and outer surfaces, wherein the coating has a thickness, and the thickness of the coating on the lower surface increases in depth towards the outer edge of the piston ring compared with its depth at a center of the lower surface.

40. The piston ring of claim 39, comprising an outer edge at a junction between the upper surface and the outer surface, wherein the thickness of the coating on the upper surface increases in depth towards the outer edge of the piston ring compared with its depth at a center of the upper surface.

41. The piston ring of claim 39, wherein the thickness of the coating on the outer surface of the piston ring is up to 20 μm.

42. The piston ring of claim 39, wherein the thickness of the coating on the upper and lower surfaces of the piston ring is up to 10 μm.

43. The piston ring of claim 39, wherein the hardness of the ta-C coating is 1000 HV or greater.

44. The piston ring of claim 39, wherein the ta-C coating is substantially hydrogen free and has an sp³ content of 80% or greater.
